(19) United States
(12) Patent Application Publication
(10) Pub. No.: US 2007/0084496 A1
(43) Pub. Date: Apr. 19, 2007

(54) Solid state power supply and cooling apparatus for a light vehicle

(76) Inventor: Bruce Alan Edey, Ontario, CA (US)

Correspondence Address: PHILIP H. HAYMOND, 7545 IRVINE CENTER DRIVE, SUITE 200, IRVINE, CA, 92618-2933, US

(21) Appl. No.: 11/580,555

(22) Filed: Oct. 13, 2006

Related U.S. Application Data
(60) Provisional application No. 60/728,171, filed on Oct. 18, 2005.

(51) Int. Cl. H01L 35/34; H01L 35/28

(52) U.S. Cl. 136/201; 136/204

(57) ABSTRACT

An apparatus and method for generating electrical current for a light mounted vehicle such as a motorcycle with thermoelectric modules. The invention includes apparel incorporating thermoelectric modules that cool or warm the body of a user.

### RELATED APPLICATIONS

This application hereby incorporates by reference and claims the priority and filing date of U.S. provisional patent application Ser. No. 60/728,171, entitled SOLID STATE POWER SUPPLY AND COOLING APPARATUS FOR A LIGHT VEHICLE, Edey inventor, filed Oct. 18, 2005.

### COPYRIGHT NOTICE

A portion of the disclosure of this patent document contains material which is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD OF THE INVENTION

The present invention relates to personal heating and cooling apparatus with thermoelectric modules. This invention relates more particularly to the use of thermoelectric modules for personal air conditioning apparatus for heating or cooling a user who is operating a mounted light vehicle, such as a motorcycle, powered by an engine that generates waste heat, such as an internal combustion engine. Waste heat is heat generated by an engine which is dissipated to the surrounding environment during normal operation of the engine. This invention also relates more particularly to generating electricity from the waste heat of the engine of the light mounted vehicle to provide power for the air conditioning apparatus and other accessories.

### BACKGROUND OF THE INVENTION

The present invention addresses two interrelated problems experienced by motorcyclists and others enduring uncomfortably warm or cold environments. Persons operating motorcycles and other vehicles that may be described as being mounted to ride and powered by heat-producing engines, where the user rides on the exterior of the vehicle and is exposed to ambient temperatures, have a difficult time keeping comfortably cool on a hot day and staying warm in a cold environment. Motorcycles are used by way of example herein but this should not be read as limiting, the apparatus and methods described may be applied for any like vehicle, such as snowmobile or four-wheeled quad vehicle. The problems encountered with heat generating engines of this size and smaller are unique owing to the limited size they must be in order to straddle the engine. Their smaller size dictates a smaller power capacity and therefore a limited electrical capacity as well. With high ambient air temperatures the necessary protective safety jackets and helmets riders use can become quite uncomfortable, and, because the operator is not otherwise enclosed it is difficult to maintain a temperature-controlled environment around the person.

Various apparatus for personal body cooling are known, such as a jacket or helmet that is provided with cooling apparatus to keep the user cool. Apparel such as this are used by persons working in high-temperature environments, motorcyclists and even astronauts. Drivers of performance race cars sometimes use these devices as well because the interior of the vehicle may become intolerably hot when air conditioning equipment has been removed from the car for weight loss and power gain. Although a variety of personal cooling devices exist the capacity of those devices to cool is limited with respect to mounted vehicles because such smaller vehicles usually have a minimal electrical current supply, owing to the smaller capacity engines and generators or alternators that are typically used to supply electrical current in such vehicles. The capacity of the stock electrical system for generating current is usually needed to power engine components and essential accessories such as lights. Weight and size requirements usually restrict the size of electrical storage components as well, for example lead-acid batteries that may be used with such vehicles. These deficiencies may prevent the use of an adequate cooling system requiring an electrical supply designed to cool a motorcyclist because the cooling system presents too much of a power load on an existing electrical system, limiting the cooling capacity of any such cooling system. Auxiliary or larger generators may be fitted to the motorcycle to provide sufficient energy for cooling needs, but this in turn causes a power loss for moving the motorcycle itself. This problem is exacerbated in some motorcycles because they are designed to be lightweight and employ a simple magneto for electrical current generation towards this end. A typical magneto will have sufficient electrical output to power the vehicle only, with little or no excess electrical capacity beyond that of running the engine itself.

There are a variety of different personal cooling devices available and that require different amounts of electrical energy to operate them, but there is generally a direct relationship between the power consumption and cooling capacity of any cooling air conditioning system. The simplest devices, with generally the lowest power consumption, use pre-cooled substances such as water or ice that is inserted into or circulated through a garment such as a jacket. An electrical pump or fan might be employed to circulate water or other coolant through the garment. For example Frisby Technologies, Inc., of Winston-Salem, N.C. offers various of vests and jackets having pre-cooled heat-absorbing sources built into the vest. Their SteeleVest vest products may use a gel-ice or other phase change materials that have higher freezing points, perhaps 55 to 65 degrees Fahrenheit. They also offer a vest that incorporates evaporative cooling by storing water in layered material, designed to evaporate water that is stored in the center layer through wicking. Some cooling systems and apparel have been specifically directed to use by a motorcyclist. U.S. Pat. No. 4,722,099 describes a protective motorcycle garment which allows ambient air to flow through the garments to dissipate heat. The air which flows through the garment is not cooled so that the cooling effect is very limited, and dependent on the ambient air temperature. Air-conditioned jackets are used in Japan having two built-in electric fans in the back and above the waist, the air is piped along the wearer's body and exhausts at the cuffs and the neckline.

Devices using a liquid pump to circulate water or other coolant through the garment generally require a greater electrical load to operate. For example the Cool Shirt available from Shafer Enterprises LLC of Stockbridge, Ga. is a tee-shirt having affixed capillary tubing. Cool liquid is pumped through the tubing and thereby past the body of a user to act as a heat exchanger. A similar shirt is the FAST® Personnel Industrial Cooling Suit System, made by Fresh Air Systems Technologies, Inc. of Arlington, Ill., which also employs a shirt having tubing sewn on the exterior to pump coolant through. A similar heat transfer vest or jacket is available as part of a cooling system, the K&P Tempsuit system is made by the I/O Sport Racing company of LaFayette, Calif. The K&P Tempsuit is a hooded vest with tubing an ice chest and a water pump mounted on the chest area of the vest to move the water through the tubes. Cool water is pumped from the separate container to cool the individual. The suit is connected to the cooling unit by quick release, drybreak connectors and temperature control is accomplished by a variable timer that cycles the pump on and off at various rates. A similar product known as the Eliminator vest, is available from the Jenkins Comfort Systems company of Augusta, Ga. The Eliminator is a vest touted as made of an evaporative polymer material layered around a patented liquid filled bladder, when moistened will retain its cooling properties for one to four hours. The bladder is periodically recharged by being pumped with ice-cooled water. These devices may be used in conjunction with a conventional or other type of refrigeration device to refrigerate the coolant, causing an even greater power load on the engine's electrical supply.

Other types of devices are available as well, each of which have varying energy demands. The ClimaTech Safety AirVest vest, made by the SummitStone Corporation of White Stone, Va., incorporates a simple air bladder within a vest to cool the user. Non-apparel types of devices are also used, such as the Personal Cooling System 2.0, available from the Sharper Image of San Francisco, Calif.; this device is a plastic ring having a miniature evaporative cooler and an electrically-powered fan that is draped over the user's neck. Other devices are limited to keeping the user's head cool by cooling the helmet worn by a user itself. An energy savings is thought to be realized by limiting the cooling system to the head of a user. The Pump Systems Corporation of Annville, Pa. offers its Model 310 Professional Driver Air Conditioner, which is an system that blows and circulates conventionally cooled air through the helmet. The TE Technology, Inc. company of Traverse City, Mich. designed a helmet having a thermoelectric cooling module to keep the head of a user cool.

Guttman, U.S. Pat. No. 6,510,696 attempts to solve the problem of cooling a motorcyclist by using thermoelectric cooling modules to cool a medium such as air and circulate the medium through a garment worn by the motorcycle rider. The air-conditioning apparatus includes a cumbersome housing mounted on the rear of a motorcycle and having a plurality of thermoelectric modules for cooling, two heat exchangers and a temperature regulator. Electrical current from the motorcycle engine's electrical system is used to power the thermoelectric elements, to cause a reduction or increase of temperature and air flow is forced to flow over a connected heat exchanger. The conditioned air is then blown or pumped through a garment similar to those of the prior art, to cool or heat the motorcycle rider.

The Guttman device, however suffers from size and power consumption problems, as well as the need for a user to be tethered to the device with air ducting or liquid conduits. Presumably only larger vehicles motorcycles can employ the Guttman device because they have larger power plants with sufficient capacity to generate excess electrical current to power the air-conditioning components. Smaller motorcycles and those using only a magneto might not be able to use the Guttman device at all.

The evaporative systems and those circulating coolant though and ice chest, mentioned above, are examples of alternative cooling systems. Each alternative system has its advantages and drawbacks. These evaporative cooling systems and simple ice containers require little power, at least a fan or pump to move coolant through the riders apparel but while these systems require little electrical current power they are bulky and/or have limited cooling capacity. Ice chests must be replenished with ice as well. Conceivably cooling can be achieved by a common Carnot compressor-based system. In a Carnot system cooling is achieved by vaporizing a refrigerant such as a chlorofluorocarbon to cool coolant, the coolant could then be pumped or blown through ducting or tubing to cool a rider. In this system heat is absorbed by the refrigerant through the principle of the “latent heat of vaporization” where the coolant is released to vaporize to cause cooling, then the vapor is condensed and compressed into a liquid again with a compressor. Because conventional Carnot cooling devices require that heat be carried away by a refrigerant moved by a compressor, moving parts that can cause equipment breakdowns and are bulky and heavy as well. Many compressor-based systems are sensitive to orientation to the ground and can malfunction if not kept in a position relative the ground; this requirement is not as compatible with use of a small mounted vehicle such as a motorcycle, which leans to and fro during operation. A conventional Carnot cooling device presents substantial electrical or mechanical energy demands on the small mounted vehicle as well, demands that may make use of the vehicle with such a cooling system impractical.

When used to generate electricity, a thermoelectric module is called a thermoelectric generator (TEG). When used as a heat pump a thermoelectric module is referred to as a thermoelectric cooler or cooling module (TEC).

Although a thermoelectric system such as Guttman might only be practical to use on larger motorcycles because of power consumption, only practical with motorcycles that have engines with electrical systems of large enough capacity to power a TEC module array, thermoelectric modules used as TEC's have many advantages over alternatives such as Carnot-cycle type of refrigeration unit. Thermoelectric devices are relatively light and have no moving parts and therefore also need little or no maintenance. A thermoelectric module also has an extraordinarily long life, perhaps as much as 100,000 hours. Thermoelectric modules are not dependent on orientation as a compressor-based system might be, so they are much more amenable to use of a mounted light vehicle such as a motorcycle which is constantly changing its orientation during operation. Thermoelectric devices are also easily controlled and do not require a liquid refrigerant to achieve cooling. Simply changing the polarity of the DC power supply powering a TEC causes heat to be pumped in the opposite direction, so a cooler can then become a heater. There is also no refrigerant to replenish in connection with causing heat absorption, the cooling reaction, as there is in the typical compressor-based system.

Generally then, a problem for any personal air conditioning system suitable for use by an operator of a mounted vehicle powered by an internal combustion engine is that the cooling system the drain on the electrical system of the vehicle. The various types of cooling systems incur different energy costs, roughly in proportion to the cooling capacity of the system, using pre-cooled material, a fan, an evaporative cooler, a pump used to move pre-cooled liquid, and devices that can themselves lower the temperature of a coolant, such as a standard compressor. Most of these devices are difficult and cumbersome to use by motorcyclists for other reasons as well, for example the motion and limited storage capacity of a motorcycle for example reduces the ability to carry and stabilize any cargo, much less liquid containers.

The above then presents two problems, that of cooling a motorcycle rider and of obtaining an electrical current supply of adequate capacity. Therefore, due to the energy demands of any personal cooling system and the limited electrical capacity of a motorcycle electrical system, cooling ability and power production present an inherently interrelated limiting factor in the design of any cooling apparatus for a motorcyclist. In addition to the use of supplementary alternators or generators on such a vehicle, a supplementary thermoelectric source of electrical power has been used with internal combustion engines, using Peltier thermoelectric modules to convert heat from the exhaust of the engine to generate electricity. This heat dissipation system uses heat transmission through thermoelectric modules to provide electricity for auxiliary devices such as air conditioning systems on the vehicle.

The TEG exhaust manifold made by Hi-Z Technology, Inc. of San Diego, Calif. is an example of such a system. Thermoelectric generators have long been used in special applications to generate electricity from heat. For space exploration for example, particularly in deep space where the light from the sun is too weak to power a spacecraft with solar panels, the electrical power has been provided by converting the heat from a radioactive heat source into electricity using thermoelectric generators.

What is needed then is a personal cooling apparatus that does not encumber a user, leaving him free to operate the operate the vehicle such as a motorcycle. What is also needed is a supplementary power source for a motorcycle, snowmobile or other mounted light vehicle to supplement the inherently limited electrical supply capacity of such a mounted vehicle and allow the use of accessory items such as air conditioning. What is also needed is an optimum combination of such a personal cooling apparatus together with a power supply of sufficient capacity to adequately cool a user and without the cumbersome or inefficient drawbacks of the apparatus of the prior art.

### SUMMARY OF THE INVENTION

A solution to the above has been devised. One aspect of the current invention is a supplementary electrical supply for a mounted light vehicle powered by a heat generating engine that converts waste heat from the engine to electrical current using a thermoelectric module as a generator to power an air conditioning system. Another aspect of the current invention is apparel such as a jacket or vest having one or more thermoelectric modules as cooling devices that use electrical current to cause cooling and generate heat to cause heating. Another aspect of the current invention is to use a TEG on a mounted light vehicle in combination with a variety of electrically powered personal cooling systems.

The invention includes methods and apparatus including a waste heat generator TEG current source for a light mounted vehicle having one or more thermoelectric modules having first and second sides, with positive and negative leads, and each thermoelectric module has a side in thermal communication with the waste heat of the engine, so that the waste heat causes the thermoelectric module to generate an electric current flow, forming a TEG. A typical engine has an exhaust system and the side in thermal communication with the waste heat of the engine is affixed to the exhaust system of the light mounted vehicle. The exhaust system usually includes a muffler and in the preferred embodiment the heated first side is in thermal communication with the muffler, being mounted concentrically about the muffler. Heat my be dissipated away from the second side of the TEG with a heat sink, including a fan or by using a liquid heat exchanger to move waste heat away from the thermoelectric module.

The TEG may be connected to the existing electrical system of the motorcycle or used separately. For example the TEG may be connected to the vehicle's battery through the leads. Therefore the system can be used alone or with an electrical system having very limited surplus capacity, such as a vehicle using a magneto as a mechanical generating source.

The electrical current may be used to power apparatus to cause the body of a rider of the vehicle to be warmed, or the cooled side of the second side of the thermoelectric cooling module is adapted to cause the body of the rider of the light mounted vehicle to be cooled. For example the TEG electrical current could be used to heat air or liquid then blown or pumped about the body of a rider.

The apparel of the apparatus to cool or warm a rider may be used independently as well, with or without the waste heat generator and with or without a mounted light vehicle. Apparel of various designs covering a portion of the body of a rider or user are encompassed in the present invention, with TEC's directly affixed to the apparel and adapted to heat or cool the rider. The modules may further be arranged or incorporate materials to act as protective gear to protect the rider front injury during a crash.

In one embodiment thermoelectric cooling modules are adapted to heat or cool air in contact with the body of the rider. Zone cooling may be implemented as well, where two or more TEC's heat or cool portions of air in contact with the body of the rider at different rates in response to environmental temperature measurement.

In another embodiment a heat exchanger carrying a liquid coolant is incorporated into the apparel to impart heat exchange with the body of a rider or user. Tubing carrying the liquid coolant is circulated through the apparel. The tubing may be subdivided for zone cooling as well, heating or cooling the coolant that is circulated through different lengths of the tubing at different rates in response to environmental temperature measurement with a thermostat.

In yet another embodiment of a heat exchanger carrying liquid coolant one or more reservoirs for the liquid coolant such as a bladder are incorporated into the apparel and held against the body to impart heat exchange with the body of a rider or user and the TEC's raise or lower the temperature of the liquid coolant. If two or more reservoirs are used zone cooling can be implemented, heating or cooling different reservoirs at different rates in response to environmental temperature measurements with a thermostat.

Before explaining at least one embodiment of the invention in detail it is to be understood that the invention is not limited in its application to the details of construction and to the arrangements of the components set forth in the following description or illustrated in the drawings. The invention is capable of other embodiments and of being practiced and carried out in various ways. Also, it is to be understood that the phraseology and terminology employed herein are for the purpose of description and should not be regarded as limiting and that many changes, modifications, and substitutions may be made by one having ordinary skill in the art without departing from the spirit and scope of the invention. Additional aspects and advantages of the present invention are set forth in the following description and claims, particularly when considered in conjunction with the accompanying drawings in which like parts bear like reference numerals.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

### BRIEF DESCRIPTION OF THE DRAWINGS

FIG. 1 is perspective view of a diagram of a thermoelectric module.

FIG. 2 is a side view of an embodiment of the invention, a diagram of a light mounted vehicle, here a motorcycle.

FIGS. 3A and 3B are side and rear views of an embodiment of the waste heat generator invention used on small a light mounted vehicle.

FIG. 4 is a side views of an embodiment of the invention, shown on a diagram of a motorcycle.

FIGS. 5A-5C are front diagrammatic views of cooling apparel of the present invention.

### DETAILED DESCRIPTION OF THE INVENTION

The following description, and the figures to which it refers, are provided for the purpose of describing examples and specific embodiments of the invention only and are not intended to exhaustively describe all possible examples and embodiments of the invention.

The invention presents several embodiments of apparatus employing thermoelectric modules that, when used with any small vehicle such as a motorcycle where the engine generates waste heat, can be used to power accessories and further to cool the rider of the vehicle. One aspect of the present invention is a supplementary electrical current source from thermoelectric modules for generating supplementary electrical current. Another aspect of the present invention are several embodiments of new apparel that can be used to cool a rider of such a small vehicle. Yet another aspect of the present invention is the combination of these apparatus to create a practical system for cooling a rider.

Thermoelectric modules are known in the art. A thermoelectric module is a small solid state device that can operate as a heat pump or as an electrical power generator using the Peltier effect. The Peltier effect occurs when DC electrical current flows through two dissimilar conductors. Depending on the direction of current flow, the junction of the two conductors will either absorb or release heat. Conversely, when heat is applied to a thermoelectric module it will generate electricity.

Bismuth telluride is a favored semiconductor material used to create either an excess (n-type) or a deficiency (p-type) of electrons type of thermoelectric device, but different materials known to those of skill in the art are favored depending on the application and whether the thermoelectric module is to be used as a TEG of or a TEC. A typical thermoelectric module consists of a number of p- and n-type pairs (couples) connected electrically in series and sandwiched between two ceramic plates, but could also be a series of only p- or only n-semiconductors. When connected to a DC power source, current causes heat to move from one side of the module to the other. This creates a hot side and a cold side on the module. A typical TEC application for a thermoelectric module exposes the cold side of the TEC to the object or substance to be cooled and the hot side to a heat sink which dissipates the heat removed to the environment. If the current is reversed, the heat is moved in the opposite direction, the hot face becomes the cold face and vice-versa. Thermoelectric modules therefore can be used to heat and to cool, depending on the direction of the DC current, as well to generate electrical current. Different combinations of solid state materials are generally preferred when a thermoelectric module is used as a TEC or a TEG. As recited above, thermoelectric modules suitable for use as a TEC are available from the TE Technology, Inc. company of Traverse City, Mich. Thermoelectric modules suitable for use as a TEG are available from the Hi-Z Technology, Inc. company of San Diego, Calif.

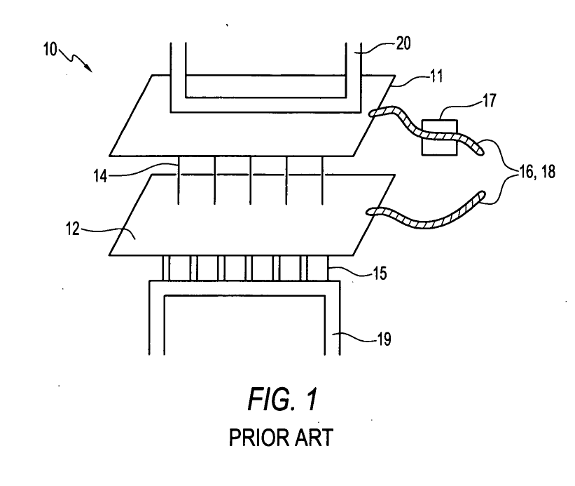

Referring now to FIG. 1, a generic thermoelectric module 10 is shown. A typical thermoelectric module 10 has two thermoelectric support structures, here thin ceramic wafers 11 and 12 with a series of p- and n-doped semiconductor materials 14 sandwiched between them. The ceramic material 11 and 12 on both sides of the thermoelectric adds rigidity and electrical insulation. A heat sink 15 is typically used to dissipate heat. The thermoelectric couples are connected electrically terminating in positive and negative leads 16 and 18 for connection to a DC power source or a load, depending on whether the thermoelectric device is being used as a TEC or TEG. An array of thermoelectric modules 10 can contain two to several hundred couples.

The amount of heat moved by a TEC is proportional to the power supplied. Temperature can be controlled manually, with a rheostat or with automatic apparatus such as a thermostat. The automatic controller 17 can range from a simple on-off thermostat to a complex computer controlled feedback circuit. Such control systems are available from a variety of manufacturers and their use an application is known to those of skill in the art.

When connected to a DC power supply the thermoelectric module 10 acts as a TEC. As DC current passes through leads 16 and 18 the thermoelectric module 10 actively pumps heat from one side to the other, 11 to 12, which heat is dissipated at heat sink 15. A heat sink is a form of conductive heat exchanger, absorbing heat and allowing it to dissipate into the ambient air, moving the heat or even absorbing heat as it is being cooled by the TEC plates 11 and 12. Fans (not shown) on each side of the TEC may be used to circulate ambient air between the fins of the heat sink 15, to dissipate the collected heat, or to move cooled air on the other plate. A TEC plate 11 and 12 may also be used with other types of heat exchangers, shown generally at 19 such as with a liquid coolant, optionally with the liquid coolant being actively moved past the plate with a pump, or actively with air being moved with a fan to allow the heating and cooling of a TEC to be applied to and heat or cool an object at a distance. This is particularly useful when a TEC is used to heat or cool other objects, to channel the heat or cooling effect to a specific area.

The specific design and selection of a thermoelectric module, the circuit and heat exchange system for use as a TEC for a particular cooling application can be assembled according to methods known to those of skill in the art.

Thermoelectric modules can also be used to generate electricity as a TEG by using a temperature gradient. The module 10 converts heat to DC electrical current. A basic TEG consists of thermoelectric module 10 that is heated on one side, a support structure such as the heat exchanger 19 is connected to one plate 11 or 12 and to a heat Source, whereby heat is conducted to the side. The other side may be equated with a heat dissipation device such as the heat sink 15. This heat dissipation system thereby favors heat transmission through the thermoelectric module 10. When heat is dissipated from one side of the thermoelectric module to the other, electrical current in generated in leads 16, 18.

Thermoelectric generators have been used in the prior art to generate supplementary electrical current for large trucks. Hi-Z Technology, Inc., located in San Diego, Calif. makes such a TEG for heavy diesel trucks. Their TEG for a truck is comprised of seventy-two thermoelectric modules (9×8 parallel circuits), which are capable of producing 1 kW of electrical power at 12 VDC during nominal engine operation. The heated sides of the modules are thermally connected to the diesel exhaust heat exchanger or manifold and the cold side is thermally connected and cooled by the engine's ordinary liquid coolant. See Thermoelectric Generator (TEG) for Heavy Diesel Trucks by John C. Bass, Aleksandr S. Kushch, Norbert B. Elsner, Hi-Z Technology, Inc., San Diego, Calif., U.S.A (presented at the Diesel Engine Emission Reduction Workshop, 6-10 August 2001, Portsmouth, Va.). The structure, use and history of different thermoelectric generators are discussed in depth in State of the Art of Thermoelectric Generators Based on Heat Recovered from the Exhaust Gases of Automobiles, Jorge Vazquez, Miguel A. Sanz-Bobi, Rafael Palacios, Antonio Arenas Proceedings of the 7th European Workshop on Thermoelectrics, Paper #17, October 2002, Pamplona, Spain. Research into advanced and more efficient thermoelectric generators is proceeding as well, the present inventions are intended to encompass those advances to thermoelectric modules as used in both thermoelectric generation and thermoelectric cooling. See, for example Development of an Underarmor 10 Kilowatt Thermoelectric Generator Waste Heat Recovery System for Military Vehicles by John C. Bass, et. al, Hi-Z Technology, Inc. 2004 DEER Conference, Session 4-Waste Heat Utilization Aug. 30, 2004.

The specific design and selection of a thermoelectric module, the circuit and heat exchange system for use as a TEG for a particular application requiring an electrical supply can be assembled according to methods known to those of skill in the art.

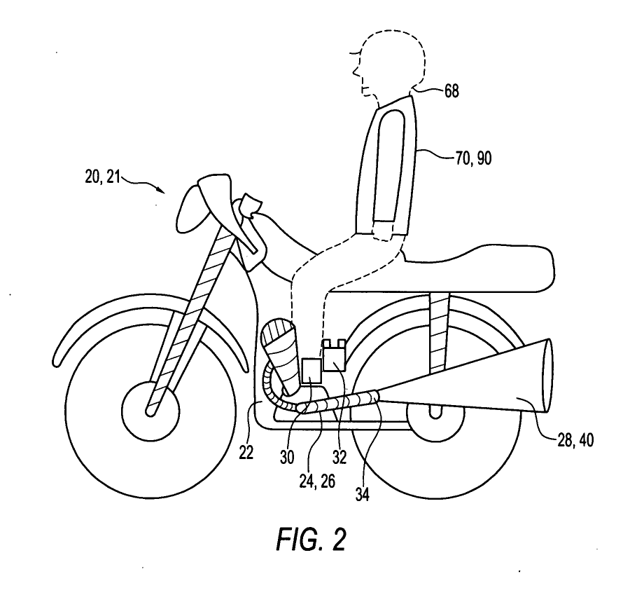

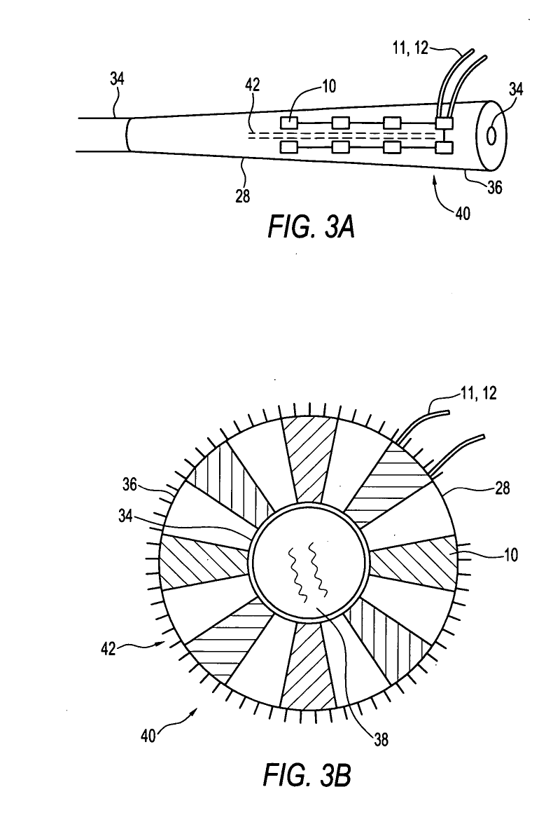

Referring further to FIG. 2 a diagram of a motorcycle 20 is shown, but this representation can be applied to any light mounted vehicle 21 with an engine that generates waste heat, such as an internal combustion engine, and that is mounted by a rider, such as a snowmobile or jet ski, having an engine 22 with an exhaust system 24. The exhaust system 24 is comprised of various components including an exhaust manifold 26 and a muffler 28, which together with other areas of the engine are heat-generating surfaces of the engine, surfaces that generate heat during normal operation of the engine 22. Thermoelectric modules 10 may be affixed to the heat generating surfaces of the exhaust system 24 to generate electrical current from the waste heat generated by the normal operation of the engine 22, for example as shown in FIGS. 3A and 3B. The engine 22 has an electrical system that includes an electrical current mechanical generating source 30 such as a generator, alternator or magneto. The mechanical generating source 30 is used to supply power to the spark plug and accessories of the vehicle 21 and may store electrical energy produced by the mechanical generating source 30 in a battery 32 as well.

FIGS. 3A and 3B show the preferred configuration where the TEG's 10 are integrated with the muffler 28. The muffler has a tailpipe 34 fitted concentrically within an exterior housing 36 of the muffler 28. TEG's 10 are affixed to the tailpipe 34 and wired together (not shown in FIG. 3B) to create a single waste heat generator 40 for generating DC electrical current. The hot side, here 12, of the TEG 10 faces the tailpipe 34 within the muffler 28 and the exterior 36 of the muffler may include a heat sink with cooling fins 42 or other heat dissipation apparatus such as coolant lines (not shown) innervating the muffler. The present invention is to include any of the many ways known to those of skill in the art to transfer the heat of the engine or exhaust gases 38 to the TEG's 10. In this embodiment then, the hot exhaust gas 38 heats the tailpipe 34 which is turn heats the hot side 12 of the TEG 10, generating a DC output for a load. Heat is dissipated from the TEG 10 though cooling fins 42.

It is essential to dissipate heat to maintain a cooling gradient between the two sides of a TEG, to allow the continuation of the generation of electrical current. Hi-Z produces a strap-on TEG kit for a hot tube and, while the appropriate number of TEG individual modules needed for a particular motorcycle may be easily calculated by those of skill in the art, a typical example for a muffler 28 configured as a waste heat generator 40 is to use an array of twenty to fifty modules of their model HZ20 thermoelectric generation modules, depending on the size of the motorcycle.

In the preferred embodiment, leads 11 and 12 from the waste heat generator 40 are connected to a battery 32 to store electrical current that has been generated. The manner in which the waste heat generator 40 may be connected to any accessory, such as a cooling system, or to the electrical system of the vehicle engine 22 can be performed a number of ways that will be apparent to those of skill in the art. If the waste heat generator 40 is connected to an existing battery 32 of an engine 22 appropriate voltage regulators must be included to prevent over-charging the battery as well as to prevent any accessory from draining the battery while the engine 22 is not operating. When connected in this way it should be noted that the contribution from the waste heat generator to the charge on a battery actually adds available power to the engine 22 because it has less need to operate an alternator. The waste heat generator may be connected directly to accessories or a second battery or capacitor as well, isolated from the electrical system of the engine 22. In all cases where a battery is employed a voltage regulator or diode or other such device should be included to prevent the battery from powering the array of thermoelectric devices in the waste heat generator, in other words to operate them as TEC's and perhaps drain the battery.

A waste heat generator of the above description affords advantages and efficiencies unique to a light mounted vehicle. These vehicles typically come equipped with marginal or minimal electrical systems owing to the limited size and therefore electrical-generating capacity of their engines. Air cooling systems and other accessories may therefore be otherwise be impractical or impossible to use with a light mounted vehicle. This also affords an element of safety because the waste heat generator 40 will allow extended operation of the engine 22 should the standard electrical recharging system fail. A kit may be provided to retrofit existing motorcycles and other light mounted vehicles.

The waste heat generator 40 is particularly useful for supplying a steady current with vehicles 21 that use a magneto as a power source 30. Some mounted light vehicles 21 such as off-road dirt bikes use a magneto as a mechanical generating source 30 instead of a generator or an alternator in combination with a battery. Magneto systems are limited in their output, but magnetos are light in weight and very reliable power sources. These vehicles generate power for the engine ignition system with the magneto, which is basically an AC electrical generator that has been tuned to create a periodic high-voltage pulse rather than continuous current. When auxiliary electrical components such as lights are needed a battery is commonly included to store energy for these accessories and the waste heat generator 40 can be used in combination with a battery to store electrical energy. The waste heat generator 40 of the present invention together with a vehicle 21 having a magneto as a mechanical generating source 30, such as a motorcycle 20 can be used without a battery too however, because it provides a continuous DC current source for operating accessories without the need for a battery as well.

The mounted light vehicle waste heat generator 40 of FIGS. 3A and 3B can be used with a multitude of electrically powered accessories, including personal cooling systems. For example the methods and devices of Guttman can be powered with such a waste heat generator rather than as by the battery of a motorcycle as described in that patent. It is believed that a Guttman device can only be used with larger motorcycle engines having larger alternators, so the present invention will make the Guttman device usable with smaller vehicles, such as the super sport race type of vehicle.

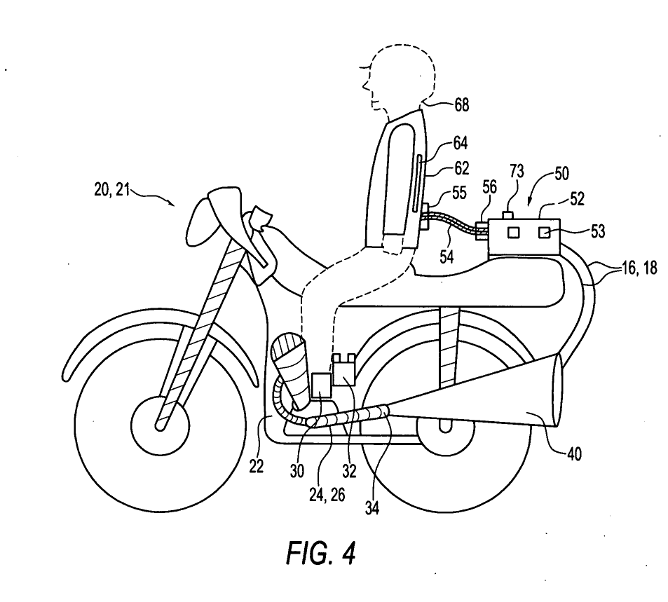

Generally, a Guttman type of device 50, shown in FIG. 4 uses electrical current from the engine through leads 16, 18 to cool coolant 54 with thermoelectric modules 53, to act as a first heat exchanger. Air or liquid is used as a refrigerant or coolant. The cooling unit 52 is a large housing that is mounted on the rear of a motorcycle 20, that receives the coolant 54 pumped or blown through tubing or ducting 55 with a fan or pump 56 that moves the coolant through the first TEC heat exchanger 58 powered by the mechanical current generating source 30 of the motorcycle's electrical system to cool or heat the coolant. After the coolant 54 is cooled or heated by the first heat exchanger, it is pumped through connecting lines 55 to personal apparel 62 worn by a motorcycle rider 68 (shown in dotted outline) that is likewise fitted with ducts or liquid coolant carrying apparel tubing 64 that communicates the coolant 54 in the tubing 55 from the first heat exchanger 58 with the ducting or tubing 64 in the apparel. The apparel 62 and tubing 64 acts as a second heat exchanger to cause cooling or warming of the body of a rider, 68. Were the polarity of the DC current powering the first TEC's 53 of the first heat exchanger to be reversed, the same apparatus would warm the coolant and therefore warm the rider. Those of skill in the art will appreciate that temperature of the apparel can be regulated by a thermostat, rheostat or equivalent switch 73 placed within the system regulating current flow to the TEC in response to the coolant or other temperature corresponding to the warming or cooling of the body of the rider.

In one embodiment existing cooling systems such as Guttman 50 can be powered or partially powered by the waste heat generator 40 of the present invention. The TEC of Guttman is one cooling source that can be used to cool or warm coolant or air 54 but the other powered cooling systems can be powered by the present invention as well.

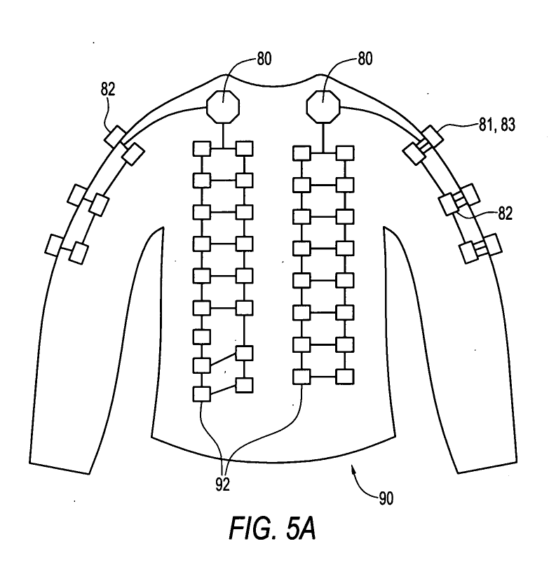

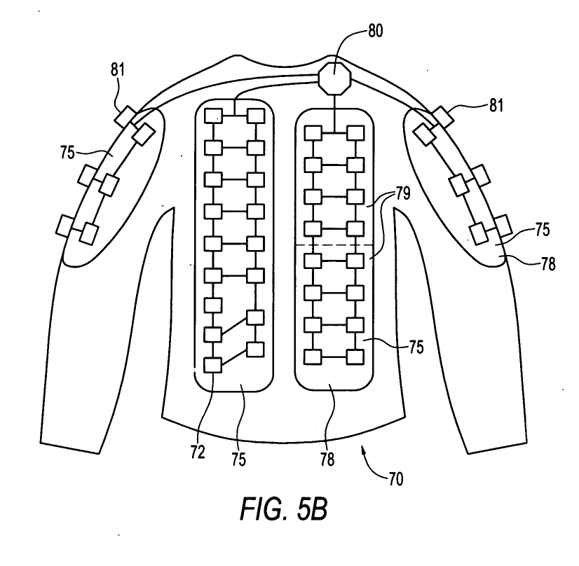

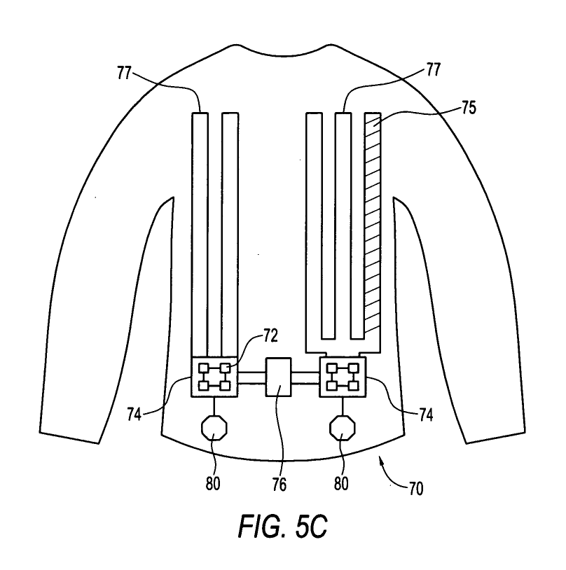

FIG. 5A shows one embodiment of torso apparel 90, but the same principal applies to arm or leg or head apparel. In this embodiment, a number of TEC's 92 are disposed within the jacket, apparel or vest. The apparel 90 itself acts as an insulator to hold TEC's 92 about the body of the user. The torso apparel 90 can be made more efficient by the use of zone cooling, where TEC's in one area of the apparel are supplied with greater electrical power to for example cause hotter areas of the user's torso to be warmed or cooled for example on the side of the user exposed to sunlight. Thermostats 80 may be disposed about the exterior of the apparel 90 as sensors to cause the different levels of power to be selectively supplied to different TEC's. As with the previous embodiment heat removed from the refrigerant can be dissipated to the outside environment by a heat sink 81, in the preferred embodiment by way of one or more aluminum disks 83, preferably having cooling fins 82 in thermal communication with the hot side of the thermoelectric modules of the TEC array 72. An array of Te Technology, Inc. TEC's may be used, for example their model CH19-10-13 or CH-43-1.0-08 thermoelectric cooling modules may be used.

Now also referring to FIG. 5B and 5C liquid coolant embodiments of the apparel is shown. Apparel such as torso apparel 70, such as a jacket, shirt or vest, and even a blanket or pants, having an array of TEC's 72 is shown. In this embodiment the TEC's are used to cool refrigerant 75 circulated within the apparel 70.

In these embodiments, which may be powered either by the waste heat generator 40, the mechanical generating source 30 or by the engine or battery 32, the TEC's cool a reservoir 74 of a refrigerant 75 such as water that is circulated by one or more pumps 76 through tubing 77 of the type used in the FAST jacket or K&P Tempsuit, or is used to cool or heat a refrigerant within a bladder 78 that conforms to the torso of the user for better heat transfer. This apparel apparatus 70 is more efficient than Guttman because it cools or heats a single refrigerant rather than cooling or heating air or another medium from ambient temperature to the desired temperature. When used with tubing 77 or a reservoir such as a bladder 78, the system is a closed loop system, with previously cooled refrigerant 75 being recirculated within the apparel.

The apparel can be made further more efficient by the use of zone cooling, where cooled or heated water is diverted to particular tubes of the tubing 77 or different bladders 78 or subdivided regions of bladders 79 (shown as either side of dotted line), to cause hotter areas of the user's torso to be differentially cooled or heated, for example the side of the user exposed to sunlight. Thermostats 80 may be disposed about the exterior of the apparel 70 to activate the pump or one of several pumps 76 to route refrigerant 75 to that area of the user's body, in response to environmental temperature, including but not limited to ambient air temperature and/or temperature of the air in contact with the body of the rider, and/or the temperature of the body of the rider.

The thermoelectric cooling modules may also be disposed within the jacket to provide additional crash protection to a rider. The areas of the jacket 70 shown as the locations of the bladder 78 shown in FIG. 5B can generally also be used to implement the TEC's 92 as protective gear, to supplement the protection afforded a user by the jacket. According to the report Motorcycle Accident Cause Factors and Identification of Countermeasures, Volume 1: Technical Report, Hurt, H. H., Ouellet, J. V. and Thom, D. R., Traffic Safety Center, University of Southern California, Los Angeles, Calif. 90007, Contract No. DOT HS-5-01160, January 1981 (Final Report), proper riding gear will help prevent or reduce injury in a crash. Soft tissue (skin and muscle) damage (road rash) as the body slides across the surface at speed. That report states that covering the body with leather or an abrasion-resistant fabric (for example Cordura®, Kevlar® or ballistic nylon) provides a higher level of injury protection and describes methods to better implement such clothing. Superior protection should be given to vulnerable areas of the body where the bone is just below the surface of the skin for example the shoulders, hips, knees and ankles, or to areas of particularly devastating injury, such as the spine.

In another embodiment the TECs of the TEC array can incorporate harder or sacrificial armor to afford additional crash protection, such as metal or plastic, or the entire array, shown generally in FIG. 5B as the bladder areas 78 can be covered by such armor. The TEC arrays can thereby be located on the jacket over a vulnerable area of the body to act as protective gear and/or can incorporate the abrasion-resistant materials recited above or armor to act as protective gear anywhere on the apparel. Heat removed from the refrigerant can be dissipated to the outside environment by a heat sink 81, in the preferred embodiment by way of one or more aluminum disks 83, preferably having cooling fins 82 in thermal communication with the hot side of the thermoelectric modules of the TEC array 72.

Of course alternative systems may be used to cause heat dissipation from the hot side of the TEC, may be used with nay of the above embodiments of apparel. Although jacket 90 is shown, this design is envisioned to include other apparel, for example vests, pants or a blanket, lined with one or more thermoelectric TEC devices to cool the interior and exhaust heat to the surrounding atmosphere. The cooling or heating of the TEG jacket is controlled with typical thermoelectric control devices known by those of skill in the art, such as a rheostat or thermostat 103.

In both embodiments 70 and 90, elimination of waste heat may also be facilitated by providing breathable material or air vents 102 disposed along the exterior of the jacket 90, adapted to allow the release of heat from the interior of the sleeve of the jacket to the surrounding environment, while still insulating the interior. Those of skill in the art will appreciate that temperature of the apparel can be regulated by a thermostat, rheostat or equivalent switch 73 placed within the system regulating current flow to the TEC in response to the coolant or other temperature corresponding to the warming or cooling of the body of the rider. Those of skill in the art will appreciate that the apparel can be used with a mounted vehicle such as a motorcycle to cool and heat a motorcyclist, but the invention encompasses all uses of the apparel, whether in connection with any sort of vehicle or not. This apparel can also be used to cool and heat a person in any conditions where such cooling or heating is required, for example the cockpit of an airplane or helicopter, a car, a tent, a sleeping bag, or a patient that is bedridden or confined to a small space.

It will be appreciated that the invention has been described hereabove with reference to certain examples or preferred embodiments as shown in the drawings. Various additions, deletions, changes and alterations may be made to the above-described embodiments and examples without departing from the intended spirit and scope of this invention. Accordingly, it is intended that all such additions, deletions, changes and alterations be included within the scope of the following claims.

The purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, which is measured by the claims, nor is it intended to be limiting as to the scope of the invention in any way.

What is claimed is:

1. A waste heat generator current source for a light mounted vehicle, comprising:
a light mounted vehicle having an engine generating waste heat,
one or more thermoelectric modules having first and second sides, positive and negative leads and each thermoelectric module having the first side in thermal communication with the waste heat of the engine, whereby the waste heat causes the thermoelectric module to generate an electric current flow.

2. The waste heat generator of claim 1 where the engine includes and exhaust system and the side in thermal communication with the waste heat of the engine is affixed to the exhaust system of the light mounted vehicle.

3. The waste heat generator of claim 1 where exhaust system includes a muffler, and the side is in thermal communication with the waste heat of the engine is affixed to the muffler of the light mounted vehicle.

4. The waste heat generator of claim 3 where the muffler in a generally elongated shape and a plurality of thermoelectric modules are arranged concentrically around the major axis of the muffler.

5. The waste heat generator of claim 3 where heat is dissipated from the second side by providing a heat exchanger on the second side of the thermoelectric module.

6. The waste heat generator of claim 5 where the heat exchanger is a heat sink having fins.

7. The waste heat generator of claim 5 where the heat exchanger includes liquid coolant to move-waste heat away from the thermoelectric module.

8. The waste heat generator of claim 1 where the side of the thermoelectric module in thermal communication with the waste heat of the engine is connected directly to a battery through the leads.

9. The waste heat generator of claim 1 where the light mounted vehicle includes a magneto as a mechanical generating source.

10. The waste heat generator of claim 1 further including a thermoelectric cooling module comprising a thermoelectric module having first and second sides,
the thermoelectric cooling module is supplied with electrical current from the waste heat generator to cause the first side of the thermoelectric cooling module to increase in temperature and the second side of the thermoelectric cooling module to cool in temperature, and
the heat from the first side of the thermoelectric cooling module is adapted to cause the body of a rider of the light mounted vehicle to be warmed, or the cooled side of the second side of the thermoelectric cooling module is adapted to cause the body of the rider of the light mounted vehicle to be cooled.

11. The waste heat generator of claim 10 including a heat exchanger comprising apparel covering a portion of the body of the rider, where the cooling side cools or the heating heats the body of the rider.

12. The waste heat generator of claim 11 where a liquid coolant or air is heated or cooled in an area outside the apparel then pumped into the apparel.

13. The waste heat generator of claim 11 where the thermoelectric cooling modules are directly affixed to the apparel and adapted to heat or cool the rider.

14. The waste heat generator of claim 10 further including one or more thermostats adapted to cause two or more thermoelectric cooling modules to heat or cool portions of air in contact with the body of the rider at different rates in response to environmental temperature.

15. The waste heat generator of claim 14 where a thermoelectric cooling module heats or cools a liquid coolant adapted to cause the body of the rider to be cooled or warmed.

16. The waste heat generator of claim 15 where the apparel heat exchanger further comprises tubing and the liquid coolant is circulated through the apparel through the tubing.

17. The waste heat generator of claim 16 further including one or more thermostats and adapted to heat or cool portions of the apparel at different temperatures in response to environmental temperature.

18. The waste heat generator of claim 15 where the heat exchanger comprises one or more reservoirs incorporated into the apparel holding the liquid coolant and the thermoelectric cooling module raises or lowers the temperature of the liquid coolant.

19. The waste heat generator of claim 18 where the reservoir comprises two or more reservoirs and further includes one or more thermostats and further adapted to heat or cool at least two different reservoirs at different rates in response to environmental temperature.

20. Apparel for heating or cooling a user, comprising:
apparel adapted to cover a portion of the body of a user including a thermoelectric cooling module comprising one or more thermoelectric modules having first and second sides,
the thermoelectric cooling module is supplied with electrical current to cause the first side of the thermoelectric cooling module to increase in temperature and the second side of the thermoelectric cooling module to cool in temperature,
the thermoelectric cooling modules are directly affixed to the apparel, and
the heat from the first side of the thermoelectric cooling module is adapted to cause the body of a user of the light mounted vehicle to be warmed, or the cooled side of the second side of the thermoelectric cooling module is adapted to cause the body of the user of the light mounted vehicle to be cooled.

21. The apparel of claim 20 where the apparel covers a portion of the torso, an arm or a leg and where the thermoelectric cooling modules are adapted to heat or cool air in contact with the body of the user.

22. The apparel of claim 21 further including one or more thermostats adapted to cause two or more thermoelectric cooling modules to heat or cool portions of air in contact with the body of the user at different rates in response to environmental temperature.

23. The apparel of claim 20 where a thermoelectric cooling module heats or cools a liquid coolant adapted to cause the body of the user to be cooled or warmed.

24. The apparel of claim 23 further comprising a heat exchanger having tubing and the liquid coolant is circulated through the apparel through the tubing.

25. The apparel of claim 24 further including one or more thermostats and adapted to heat or cool portions of the apparel at different rates in response to environmental temperature.

26. The apparel of claim 23 where the heat exchanger comprises one or more reservoirs incorporated into the apparel holding the liquid coolant and the thermoelectric cooling module raises or lowers the temperature of the liquid coolant.

27. The apparel of claim 26 where the reservoir comprises two or more reservoirs and further including a thermostat adapted to cause the heating or cooling of at least two different reservoirs at different rates in response to environmental temperature.

28. The apparel of claim 20 where the apparel is adapted to act as protective gear by locating a thermoelectric cooling module over a vulnerable area of the body.

29. The apparel of claim 20 where the apparel is adapted to act as protective gear by incorporating armor or abrasion-resistant material over a thermoelectric cooling module.

30. A method for supplying electrical current for a light mounted vehicle, comprising the steps of:
providing a light mounted vehicle having an engine generating waste heat, having one or more thermoelectric modules having first and second sides, positive and negative leads and each thermoelectric module having the first side in thermal communication with the waste heat of the engine, whereby the waste heat causes the thermoelectric module to generate an electric current flow.

31. The method of claim 30 where the engine includes an exhaust system and the side in thermal communication with the waste heat of the engine is affixed to the exhaust system of the light mounted vehicle.

32. The method of claim 31 where the exhaust system includes a muffler and the side in thermal communication with the waste heat of the engine is affixed to the muffler of the light mounted vehicle.

33. The method of claim 30 where the muffler in a generally elongated shape and a plurality of thermoelectric modules are arranged concentrically around the major axis of the muffler.

34. The method of claim 30 where heat is dissipated from the second side by providing a heat exchanger on the second side of the thermoelectric module.

35. The method of claim 34 where the heat exchanger is a heat sink having fins.

36. The method of claim 34 where the heat exchanger includes liquid coolant to move waste heat away from the thermoelectric module.

37. The method of claim 30 where the side of the thermoelectric module in thermal communication with the waste heat of the engine is connected directly to a battery through the leads.

38. The method of claim 30 where the light mounted vehicle includes a magneto as a electricity generating source.

39. The method of claim 30 further including a thermoelectric cooling module comprising a thermoelectric module having first and second sides,
the thermoelectric cooling module is supplied with electrical current from the waste heat generator to cause the first side of the thermoelectric cooling module to increase in temperature and the second side of the thermoelectric cooling module to cool in temperature, and
the heat from the first side of the thermoelectric cooling module is adapted to cause the body of a rider of the light mounted vehicle to be warmed, or the cooled side of the second side of the thermoelectric cooling module is adapted to cause the body of the rider of the light mounted vehicle to be cooled.

40. The method of claim 39 including a heat exchanger comprising apparel covering a portion of the body of the rider, where the cooling side cools or the heating heats the body of the rider.

41. The method of claim 40 where a liquid coolant or air is heated or cooled in an area outside the apparel then pumped into the apparel.

42. The method of claim 40 where the thermoelectric cooling modules are directly affixed to the apparel and adapted to heat or cool the rider.

43. The method of claim 42 where the thermoelectric cooling modules are adapted to heat or cool air in contact with the body of the rider.

44. The method of claim 43 further including one or more thermostats adapted to cause two or more thermoelectric cooling modules to heat or cool portions of air in contact with the body of the rider at different rates in response to environmental temperature.

45. The method of claim 41 where a thermoelectric cooling module heats or cools a liquid coolant adapted to cause the body of the rider to be cooled or warmed.

46. The method of claim 45 where the apparel heat exchanger further comprises tubing and the liquid coolant is circulated through the apparel through the tubing.

47. The method of claim 46 further including one or more thermostats and adapted to heat or cool portions of the apparel at different temperatures in response to environmental temperature.

48. The method of claim 45 where the heat exchanger comprises one or more reservoirs incorporated into the apparel holding the liquid coolant and the thermoelectric cooling module raises or lowers the temperature of the liquid coolant.

49. The method of claim 49 where the reservoir comprises two or more reservoirs and further including one or more thermostats and further adapted to heat or cool at least two different reservoirs at different rates in response to environmental temperature.

50. The method of claim 30 where the apparel is adapted to act as protective gear by locating a thermoelectric cooling module over a vulnerable area of the body.

51. The method of claim 51 where the apparel is adapted to act as protective gear by incorporating armor or abrasion-resistant material over a thermoelectric cooling module.

52. A method for heating or cooling a user, comprising the steps of:
providing apparel adapted to cover a portion of the body of a user including a thermoelectric cooling module comprising one or more thermoelectric modules having first and second sides,
the thermoelectric cooling module is supplied with electrical current to cause the first side of the thermoelectric cooling module to increase in temperature and the second side of the thermoelectric cooling module to cool in temperature,
the thermoelectric cooling modules are directly affixed to the apparel,
the heat from the first side of the thermoelectric cooling module is adapted to cause the body of a user of the light mounted vehicle to be warmed, or the cooled side of the second side of the thermoelectric cooling module is adapted to cause the body of the user of the light mounted vehicle to be cooled, and
supplying electrical current to the thermoelectric cooling module to cool or heat a user.

53. The method of claim 52 where the thermoelectric cooling modules are adapted to heat or cool air in contact with the body of the user.

54. The method of claim 52 further including one or more thermostats adapted to cause two or more thermoelectric cooling modules to heat or cool portions of air in contact with the body of the user at different rates in response to environmental temperature.

55. The method of claim 52 where a thermoelectric cooling module heats or cools a liquid coolant adapted to cause the body of the user to be cooled or warmed.

56. The method of claim 55 further comprising a heat exchanger having tubing and the liquid coolant is circulated through the apparel through the tubing.

57. The method of claim 56 further including one or more thermostats and adapted to heat or cool portions of the apparel at different rates in response to environmental temperature.

58. The method of claim 55 further comprising a heat exchanger having one or more reservoirs incorporated into the apparel holding the liquid coolant and the thermoelectric cooling module raises or lowers the temperature of the liquid coolant.

59. The method of claim 58 where the reservoir comprises two or more reservoirs and further including one or more thermostats adapted to cause the heating or cooling of at least two different reservoirs at different rates in response to environmental temperature.
